(19) United States
(12) Patent Application Publication
(10) Pub. No.: US 2009/0153201 A1
(43) Pub. Date: Jun. 18, 2009

(54) DIFFERENTIAL MULTIPHASE FREQUENCY DIVIDER

(75) Inventor: Wenyi Song, San Jose, CA (US)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 11/994,232

(22) PCT Filed: Jun. 30, 2006
(86) PCT No.: PCT/IB06/52216

§ 371 Date: Oct. 24, 2008

Related U.S. Application Data
(60) Provisional application No. 60/696,490, filed on Jun. 30, 2005.

(51) Int. Cl. H03K 23/00

(52) U.S. Cl. 327/115

(57) ABSTRACT

A multiphase divider comprises several differential latches connected in a ring. The number of latches in the ring is equal to the number of phases produced and the divisor applied to the input clock. The differential Q-outputs of one latch stage are connected to the corresponding differential D-inputs of the next latch stage. For even numbers of latch stages, the differential clock inputs of each are connected together and alternately to the divider clock input and its complement. The last differential Q-output is returned and cross-connected to the differential D-inputs of the first latch stage. For odd numbers of latch stages, the differential clock inputs of each are respectively connected in parallel to the divider clock input and its complement. The last differential Q-output is returned and straight-connected to the differential D-inputs of the first latch stage.

The present invention relates to electronic digital circuitry, and more particularly to circuits and methods for constructing differential multiphase frequency dividers.

Digital frequency dividers are used in computer and communications circuits to synthesize various utility clocks from a reference oscillator. A digital frequency divider takes a clock signal “cki” as the input, and outputs a new clock signal “cko”. The frequency of cko is the frequency of cki divided by an integer. Such dividers can be implemented in logic as fixed divisor divide-by-n, or programmable divisor divide-by-m.

Synchronous-type dividers and counters clock all the memory elements in parallel with one clock. Programmable digital frequency dividers can be implemented with finite-state-machines (FSM), e.g., with pencil-and-paper, or using logic synthesis tools such as Synopsys Design Compiler. Direct digital synthesis (DDS) is another method, it uses an accumulator clocked by an input cki. During every input clock cycle, the accumulator adds a fixed integer P to its content. A number “P” can be selected such that at the end of every N input clock cycles, the accumulator overflows. Thus the overflow output functions as the output “cko” of the frequency divider.

Asynchronous-type dividers and counters use a clock to trigger the first latch in a chain, and then the Q-outputs of previous stages are used to clock the next succeeding stages. For example, ripple, decade, and up-down counters employ asynchronous techniques.

Highly efficient DC/DC converters combine several switching supplies in parallel that are skewed in phase to one another. The resulting high frequency ripple is easier and cheaper to filter. The Texas Instruments TPS4009× family are two-phase, three-phase, or four-phase programmable synchronous buck controllers, for low-voltage, high-current applications powered by a 5-V to 15-V distributed supply. Multiphase converters have several advantages over single power stages, e.g., lower current ripple on the input and output capacitors, faster transient response to load steps, improved power handling capabilities, and higher system efficiency.

Each phase is typically operated at a switching frequency up to 1-MHz, resulting in an effective ripple frequency of up to 4-MHz at the input and the output in a four-phase application. A two phase design producers two outputs 180-degrees out-of-phase, a three-phase design produces three outputs 120-degrees out of phase with one another, and a four-phase design produces four outputs 90-degrees out of phase with each other.

In the TPS4009× family, the number of phases is programmed by connecting any de-activated phase PWM output to the output of an internal 5-V LDO. In two-phase operation, the even phase outputs are de-activated. The TPS4009× uses fixed frequency, peak current mode control with forced phase current balancing. Phase current is sensed by using either current sense resistors in series with the output inductors, or using the direct current resistance (DCR) of the filter inductors. The latter generates a current proportional signal with an R-C circuit.

An all digital approach to multiphase clock generation is needed to reduce circuit complexity and costs.

Briefly, a multiphase divider embodiment of the present invention comprises several differential latches connected in a ring. The number of latches in the ring is equal to the number of phases produced and the divisor applied to the input clock. The differential Q-outputs of one latch stage are connected to the corresponding differential D-inputs of the next latch stage. For even numbers of latch stages, the differential clock inputs of each are connected together and alternately to the divider clock input and its complement. The last differential Q-output is returned and cross-connected to the differential D-inputs of the first latch stage. For odd numbers of latch stages, the differential clock inputs of each are respectively connected in parallel to the divider clock input and its complement. The last differential Q-output is returned and straight-connected to the differential D-inputs of the first latch stage.

An advantage of the present invention is a divider is provided that can produce a multiphase output.

A further advantage of the present invention is a divider is provided wherein the number of latches arranged in a ring determines the divisor.

The above and still further objects, features, and advantages of the present invention will become apparent upon consideration of the following detailed description of specific embodiments thereof, especially when taken in conjunction with the accompanying drawings.

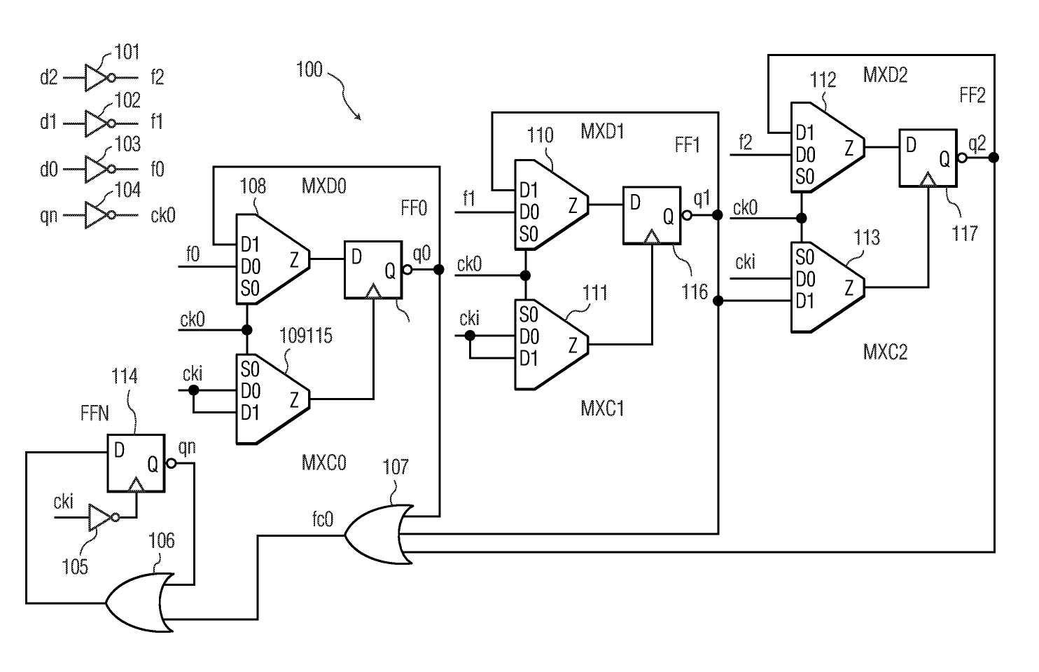

FIG. 1 is a schematic diagram of a four-phase, divide-by-four frequency divider embodiment of the present invention;

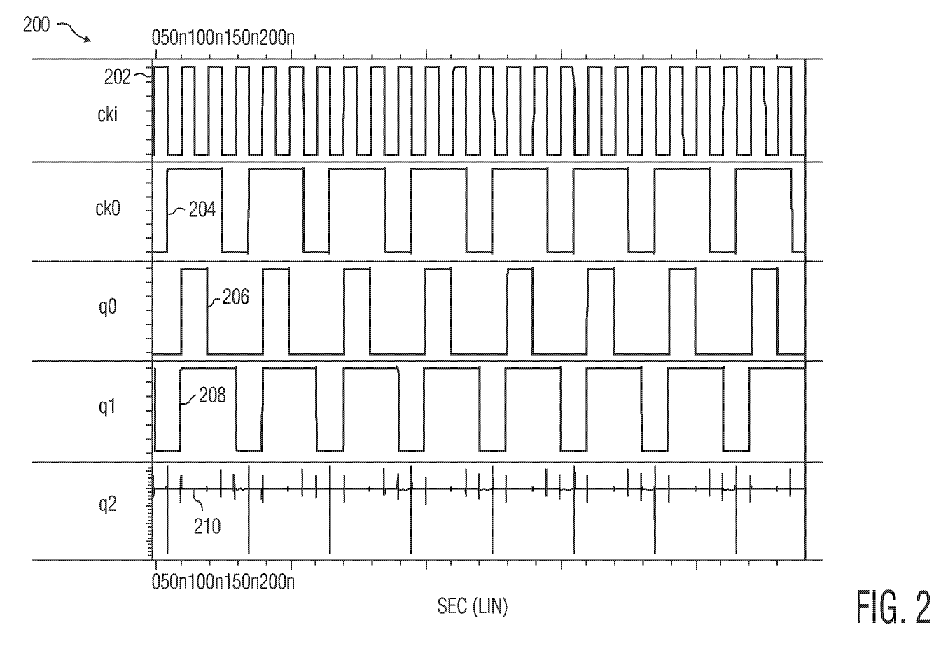

FIG. 2 is a graph showing the relationships of the clock inputs, “cp” and “cn”, in the dividers of FIG. 1, with the four-phase, divide-by-four, differential outputs p1p/p1n, p2p/p2n, p3p/p3n, and p4p/p4n;

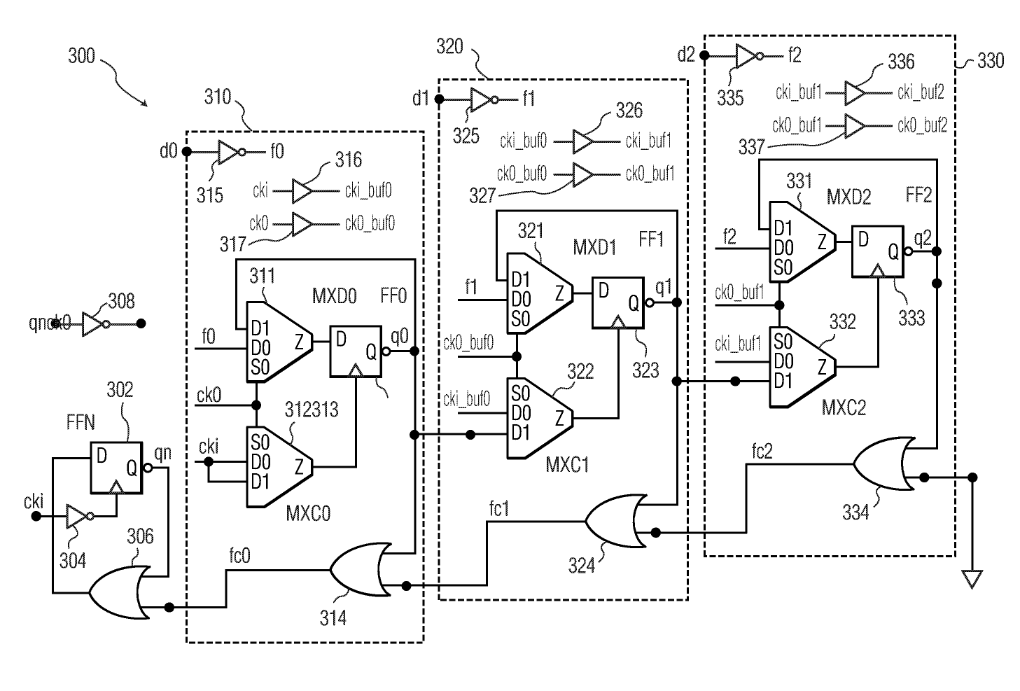

FIG. 3 is a schematic diagram of a five-phase, divide-by-five frequency divider embodiment of the present invention;

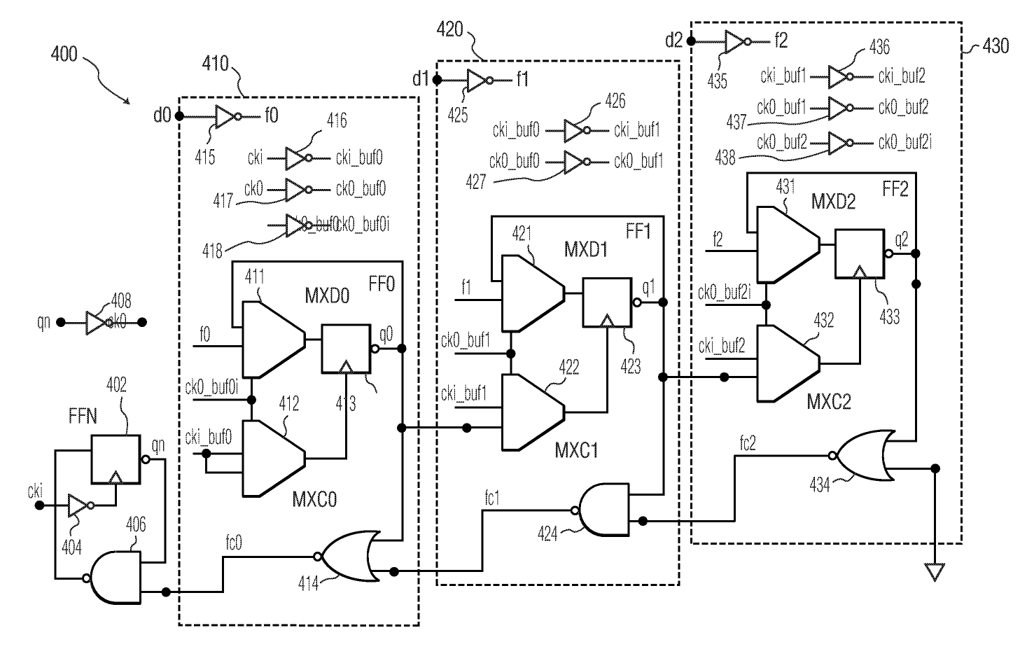

FIG. 4 is a graph showing the relationships of the clock inputs, “cp” and “cn”, in the divider of FIGS. 2 and the five-phase, divide-by-five, differential outputs p1p/p1n, p2p/p2n, p3p/p3n, p4p/p4n, and p5p/p5n; and

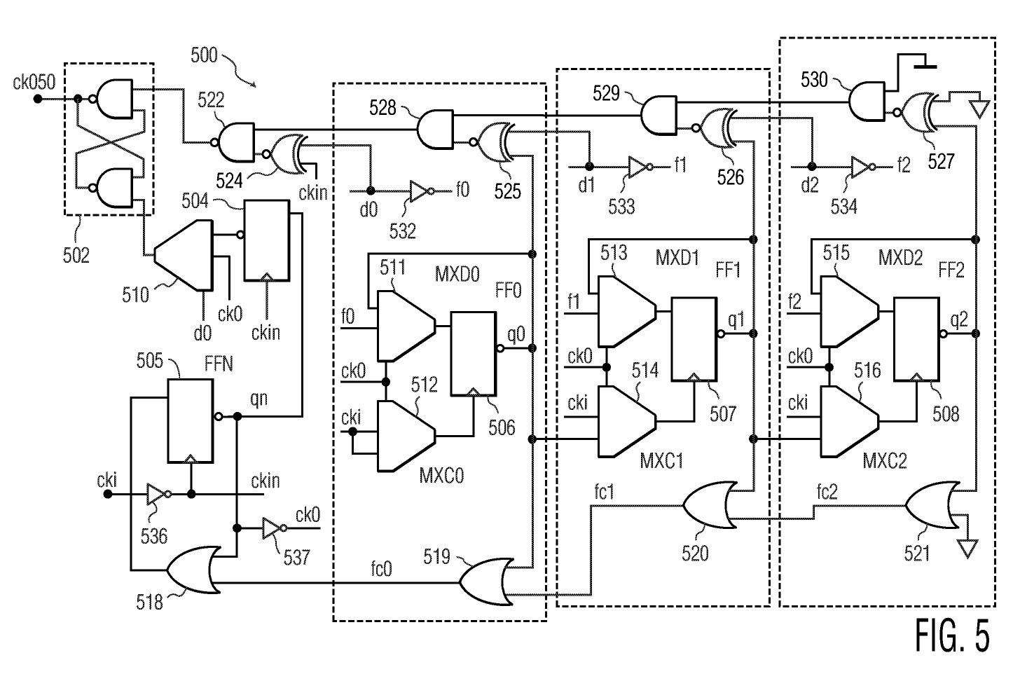

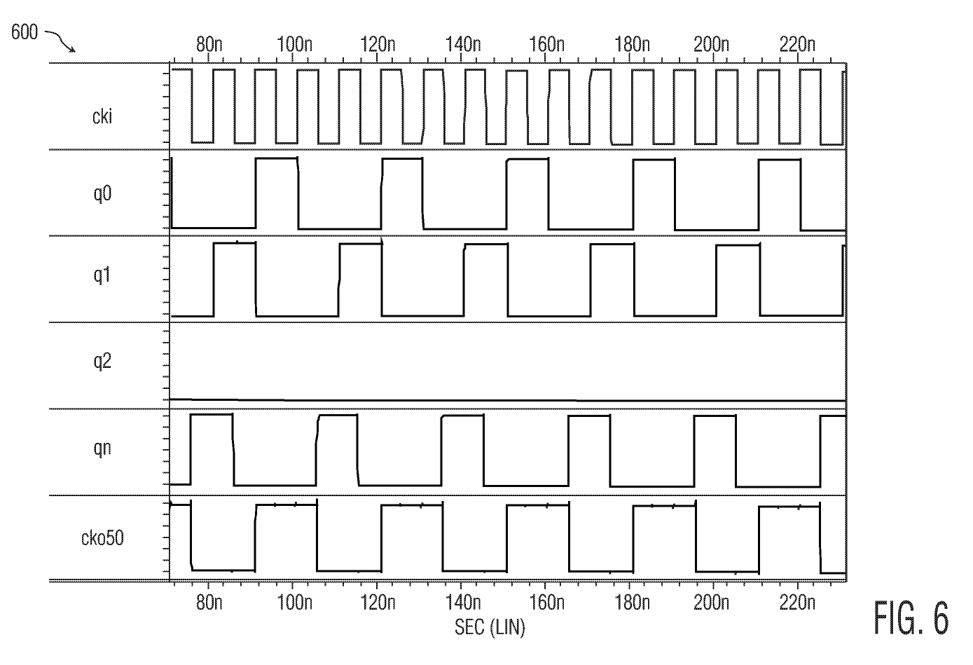

FIGS. 5 and 6, are schematic diagrams of nmos and pmos technology implementations of the building blocks that can be used in the dividers of FIGS. 1 and 2.

Multiphase frequency dividers have an input clock signal divided down by an integer to produce a set of phased clock output signals. The phases of the output signals are evenly spaced, and the number of phases is the same as the divisor.

FIG. 1 represents a four-phase, divide-by-four frequency divider embodiment of the present invention, and is referred to herein by the general reference numeral 100. Such divider 100 is representative of all even-number divisor embodiments of the present invention. It is constructed with four differential building blocks 102, 104, 106, and 108. A differential clock pair, “cp” and “cn”, are connected with “ckip” to the first and third blocks 102 and 106, and with “ckin” connected to the second and fourth blocks 104 and 108. The Q-outputs, qp and qn, are connected to the D-inputs, dp and dn of the next block. The qp and qn outputs of the last block 108 are cross-connected to the dp and dn inputs of the first block 102.

FIG. 2 is a graph 200 showing the relationships of the clock inputs, “ckip” and “ckin”, in divider 100, and the four-phase, divide-by-four, differential outputs p1p/p1n, p2p/p2n, p3p/p3n, and p4p/p4n.

FIG. 3 represents a five-phase, divide-by-five frequency divider embodiment of the present invention, and is referred to herein by the general reference numeral 300. Such divider 200 is representative of all odd-number divisor embodiments of the present invention. It is constructed with five differential building blocks 302, 304, 306, 308, and 310. A differential clock pair, “cp” and “cn”, are respectively connected in parallel with the respective “ckip” and “ckin” clock inputs of all the blocks. The Q-outputs of each, qp and qn, are connected to the D-inputs, dp and dn of the next succeeding block. The qp and qn outputs of the last block 310 are connected straight to the dp and dn inputs of the first block 302.

FIG. 4 is a graph 400 showing the relationships of the clock inputs, “ckip” and “ckin”, in divider 300, and the five-phase, divide-by-five, differential outputs p1p/p1n, p2p/p2n, p3p/p3n, p4p/p4n, and p5p/p5n.

FIGS. 5 and 6, respectively, represent nmos and pmos technology implementations of differential building blocks that can be used in dividers 100 and 300. In FIG. 5, the block 500 comprises a pair of clock input transistors 502 and 504 for “cp” and “cn”, a pair of data input transistors 506 and 508 for dp and dn, and cross-coupled Q-output transistors 510 and 512 for qn and qp. In FIG. 6, the block 600 comprises a pair of clock input transistors 602 and 604 for “cp” and “cn”, a pair of data input transistors 606 and 608 for dp and dn, and cross-coupled Q-output transistors 610 and 612 for qn and qp.

The operation of an even divider (e.g., 100) differs from that of an odd divider (e.g., 300). In the even type shown in FIG. 1, the “cp” and “cn” inputs of each block are connected together, at each block either to the “cp” or “cn” of the divider input clock signal. When the respective clock turns on the two transistors 502 and 504, or 602 and 604, the block operates like a differential buffer/inverter. When such clock turns off both, the Q-output is determined by the two cross-connected transistors 510 and 512, or 610 and 612. The output state is therefore decided by the previously sampled D-inputs.

In the odd type shown in FIG. 3, the “cp” and “cn” inputs of all the blocks are respectively connected in parallel to the divisor input clock “cp” and its complement “cn”. In each half clock cycle, the clock enabled half of the block samples its D-input. The other half holds its previous state. The half doing the sampling can transfer its D-input to the Q-output. For the nmos type block 500, when the D-input is low, the half output is still in the high impedance. In the next half clock cycle, then other half will be sampling. The inputs are complementary, so the input of the other half will be high, thus enabling its half output to go low.

To divide by an even-integer “E”, E-number of building blocks are connected together in a ring. For each block used, its “cp” and “cn” inputs are connected together, and then to alternately either the input clock or its complement. The input to output data connections end-to-end have a complementary phase relation. Each block can be connected as either a differential buffer or a differential inverter. In FIG. 1, all but one of the E blocks are connected as differential inverters, the last one (108) is connected as a differential buffer.

Given an odd-integer “O” for a divisor, 0-number of building blocks are connected into a ring. Each block's “cp” and “cn” inputs are separately connected in parallel to the two differential input clocks.

Although particular embodiments of the present invention have been described and illustrated, such is not intended to limit the invention. Modifications and changes will no doubt become apparent to those skilled in the art, and it is intended that the invention only be limited by the scope of the appended claims.

What is claimed is:

1. A multiphase divider, comprising: a plurality of differential latches each having differential D-inputs (dp and dn), differential clock inputs (cp and cn), and differential Q-outputs (qp and qn), wherein said Q-outputs are connected to the D-inputs of a next latch stage, and a last differential Q-output is returned to a first D-input; a differential divider clock input (ckip and ckin) connected to said differential clock inputs (cp and cn); and a plurality of multiphase divider outputs respectively taken in parallel from said differential Q-outputs (qp and qn) of each one of the plurality of differential latches.

2. The multiphase divider of claim 1, wherein: the number of differential latches in the plurality is equal to the integer divisor of the divider, and equal to the number of phases produced.

3. The multiphase divider of claim 1, wherein: the number of differential latches in the plurality is an even number; said last differential Q-output is returned to a first D-input and cross-connected qp to dn, and qn to dp; and said differential clock inputs (cp and cn) of each differential latch are connected together, and then to alternating ones of the differential divider clock inputs (ckip and ckin).

4. The multiphase divider of claim 1, wherein: the number of differential latches in the plurality is an odd number; said last differential Q-output is returned to a first D-input and straight-connected qp to dp, and qn to dn; and said differential clock inputs (cp and cn) of each differential latch are connected in parallel to corresponding ones of the differential divider clock inputs (ckip and ckin).

5. The multiphase divider of claim 1, wherein each differential latch comprises: a differential pair of clock transistors for cp and cn; a differential pair of data transistors for dp and dn connected in totempole respectively with the differential pair of clock transistors; and a differential pair of cross-connected Q-output transistors for qp and qn connected in totempole respectively with the differential pairs of clock and data transistors.

6. A multiphase divider, comprising: a plurality of differential latches each having differential D-inputs (dp and dn), differential clock inputs (cp and cn), and differential Q-outputs (qp and qn), wherein said Q-outputs are connected to the D-inputs of a next latch stage, and a last differential Q-output is returned to a first D-input, and wherein each latch comprises a differential pair of clock transistors for cp and cn, a differential pair of data transistors for dp and dn connected in totempole respectively with the differential pair of clock transistors, and a differential pair of cross-connected Q-output transistors for qp and qn connected in totempole respectively with the differential pairs of clock and data transistors; a differential divider clock input (ckip and ckin) connected to said differential clock inputs (cp and cn); a plurality of multiphase divider outputs respectively taken in parallel from said differential Q-outputs (qp and qn) of each one of the plurality of differential latches; if the number of differential latches in the plurality is an even number, then said last differential Q-output is returned to a first D-input and cross-connected qp to dn, and qn to dp, and said differential clock inputs (cp and cn) of each differential latch are connected together, and then to alternating ones of the differential divider clock inputs (ckip and ckin); and if the number of differential latches in the plurality is an odd number, then said last differential Q-output is returned to a first D-input and straight-connected qp to dp, and qn to dn, and said differential clock inputs (cp and cn) of each differential latch are connected in parallel to corresponding ones of the differential divider clock inputs (ckip and ckin); wherein, the number of differential latches in the plurality is equal to the integer divisor of the divider, and equal to the number of phases produced.

7. A divide-by-four, four-phase multiphase divider, comprising: a first differential latch having differential D-inputs (dp and dn), differential clock inputs (cp and cn) connected together and to a divider clock input (ckip), and differential Q-outputs (qp and qn) with a first phase (p1p and p1n); a second differential latch having differential D-inputs (dp and dn) connected to said first phase (p1p and p1n), differential clock inputs (cp and cn) connected together and to a divider clock complement input (ckin), and differential Q-outputs (qp and qn) with a second phase (p2p and p2n); a third differential latch having differential D-inputs (dp and dn) connected to said second phase (p2p and p2n), differential clock inputs (cp and cn) connected together and to said divider clock input (ckip), and differential Q-outputs (qp and qn) with a third phase (p3p and p3n); and a fourth differential latch having differential D-inputs (dp and dn) connected to said third phase (p3p and p3n), differential clock inputs (cp and cn) connected together and to said divider clock complement input (ckin), and differential Q-outputs (qp and qn) with a fourth phase (p4p and p4n) cross-connected back to the D-inputs of the first differential latch; wherein, a frequency differentially applied to said divider clock input (ckip) and complement input (ckin) will be divided by four and output in four equally spaced phases at respective Q-outputs.

8. A divide-by-five, five-phase multiphase divider, comprising: a first differential latch having differential D-inputs (dp and dn), differential clock inputs (cp and cn) respectively connected to a divider clock input (ckip) and a complement input (ckin), and differential Q-outputs (qp and qn) with a first phase (p1p and p1n); a second differential latch having differential D-inputs (dp and dn) connected to said first phase (p1p and p1n), differential clock inputs (cp and cn) respectively connected to said divider clock input (ckip) and said complement input (ckin), and differential Q-outputs (qp and qn) with a second phase (p2p and p2n); a third differential latch having differential D-inputs (dp and dn) connected to said second phase (p2p and p2n), differential clock inputs (cp and cn) respectively connected to said divider clock input (ckip) and said complement input (ckin), and differential Q-outputs (qp and qn) with a third phase (p3p and p3n); a fourth differential latch having differential D-inputs (dp and dn) connected to said third phase (p3p and p3n), differential clock inputs (cp and cn) respectively connected to said divider clock input (ckip) and said complement input (ckin), and differential Q-outputs (qp and qn) with a fourth phase (p4p and p4n); and a fifth differential latch having differential D-inputs (dp and dn) connected to said fourth phase (p4p and p4n), differential clock inputs (cp and cn) respectively connected to said divider clock input (ckip) and said complement input (ckin), and differential Q-outputs (qp and qn) with a fifth phase (p5p and p5n) straight-connected back to the respective D-inputs of the first differential latch; wherein, a frequency differentially applied to said divider clock input (ckip) and complement input (ckin) will be divided by five and output in five equally spaced phases at respective Q-outputs.
